(19) United States
(12) Patent Application Publication
(10) Pub. No.: US 2010/0169725 A1
(43) Pub. Date: Jul. 1, 2010

(54) MEMORY MODULE TESTER

(75) Inventors: Jung Kuk Lee, Yongin-si (KR); Seung Hee Mun, Yongin-si (KR); Seung Jin Seo, Suwon-si (KR); Woo-Jin Na, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/648,588

(22) Filed: Dec. 29, 2009

(30) Foreign Application Priority Data
Dec. 31, 2008 (KR) 10-2008-0137841

(51) Int. Cl. G11C 29/12; G06F 11/27

(52) U.S. Cl. 714/718; 714/E11.169

(57) ABSTRACT

a memory module test system for testing a plurality of memory modules includes a plurality buffers in one-to-one correspondence the plurality of memory modules, each of the buffers including a self-test engine for testing a corresponding memory module. The test system further includes an interface configured to receive a test program for testing the memory module, and a gate array configured to transmit the test program to the buffers using a Joint Test Action Group (JTAG) protocol and to read test results of the test program from the buffers using the JTAG protocol.

### CROSS-REFERENCE TO RELATED APPLICATIONS

A claim of priority under 35 U.S.C. §119 is made to Korean Patent Application No. 10-2008-0137841 filed Dec. 31, 2008, in the Korean Intellectual Property Office, the disclosure of which is incorporated herein by reference.

### BACKGROUND

The inventive concepts described herein relate to a memory module tester, and more particularly, to a device for testing a memory module using a buffer with a built-in self test (BIST) engine.

A memory module is generally made up of a plurality of semiconductor memory devices (such as memory chips or chip packages) mounted on a printed circuit board (PCB). There are basically two ways in which the memory module can be tested after fabrication, namely, the memory module can be tested using memory module test equipment or the memory module can be tested after being installed in a system in which the memory module is actually used, that is, in a real-world environment.

When the memory module test equipment is used, the memory module is tested in an experimental setting which may not accurately duplicate a real-world environment. Accordingly, the accuracy of the test is not satisfactory.

Contrarily, when the memory module is tested in a real environment (hereinafter, referred to as an “on-board test” method), an accurate test can be accomplished. For this reason, the “on-board test” method is increasingly used these days. However, the “on-board test” method is not effective in testing large-capacity and high-speed memory modules. When a large-capacity memory module is tested using this method, test time increases and mass productivity decreases. Moreover, high-speed memory modules such as unbuffered dual in-line memory modules (UDIMMs), registered dual in-line memory modules (RDIMMs), and fully buffered dual in-line memory modules (FBDIMMs) cannot be tested using this method.

### SUMMARY

According to an aspect of the inventive concepts, a memory module test system for testing a plurality of memory modules is provided. The test system includes a plurality buffers in one-to-one correspondence the plurality of memory modules, each of the buffers including a self-test engine for testing a corresponding memory module. The test system further includes an interface configured to receive a test program for testing the memory module, and a gate array configured to transmit the test program to the buffers using a Joint Test Action Group (JTAG) protocol and to read test results of the test program from the buffers using the JTAG protocol.

According to another aspect of the inventive concepts, a memory module tester is provided which includes a socket for receiving a memory module to be tested, a buffer operatively coupled to the socket, an interface configured to receive a test program for testing the memory module, and a gate array configured to transmit the test program to the buffer using a Joint Test Action Group (JTAG) protocol and test results of the test program from the buffers using the JTAG protocol.

### BRIEF DESCRIPTION OF THE DRAWINGS

The above and other aspects and features of the inventive concepts will readily apparent from the detailed description that follows, with reference to the accompanying drawings, in which:

FIG. 1 is a schematic block diagram of a memory module tester according to an embodiment of one or more inventive concepts described herein;

FIG. 2 is a schematic diagram for use in explaining a test operation of the memory module tester illustrated in FIG. 1;

FIG. 3 is a schematic block diagram of a memory module tester according to another embodiment of one or more inventive concepts described herein; and

FIG. 4 is a schematic diagram for use in explaining a test operation of the memory module tester illustrated in FIG. 2.

### DETAILED DESCRIPTION OF THE EMBODIMENTS

The inventive concepts now will be described more fully hereinafter with reference to the accompanying drawings, in which embodiments of one or more of the inventive concepts are shown. This inventive concepts may, however, be embodied in many different forms and should not be construed as limited to the embodiments set forth herein. Rather, these embodiments are provided so that this disclosure will be thorough and complete, and will fully convey the scope of the inventive concepts to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

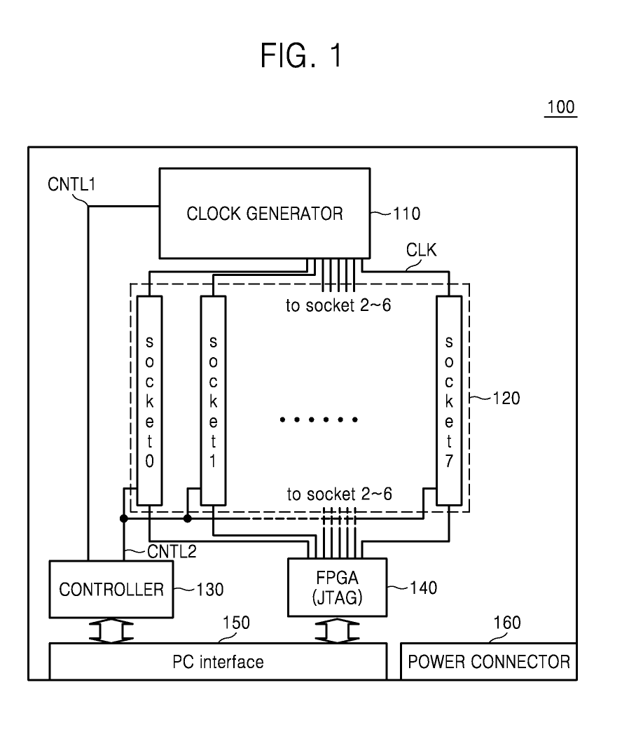

FIG. 1 is a schematic block diagram of a memory module tester 100 according to an embodiment of one or more of the inventive concepts described herein. In this embodiment, the memory module to be tested is equipped with a buffer having a built-in self test (BIST) engine.

Referring to FIG. 1, the memory module tester 100 of this example includes a clock generator 110, a socket unit 120, a controller 130, a field programmable gate array (FPGA) 140, a personal computer (PC) interface 150, and a power connector 160.

The socket unit 120 includes one or more sockets 0, 1, . . . , and 7, each of which is configured to receive a memory module, e.g., a fully buffered dual in-line memory module (FBDIMM). As mentioned above, the memory module mounted in each socket includes a buffer with a BIST engine for self-testing of the memory module.

The clock generator 110 generates a clock signal CLK in response on a first control signal CNTL1 from the controller 130, and outputs the clock signal CLK to each socket of the socket unit 120.

The controller 130 supplies the first control signal CNTL1 to the clock generator 110, and a second control signal CNTL2 to the sockets of the socket unit 120.

In operation, the controller 130 controls the operation of the memory module tester 100 based on a pre-stored control program or based on signal commands input through the PC interface 150. In particular, when a memory module to be tested is placed in the socket unit 120, the controller 130 initiates testing by outputting the first control signal CNTL1 to the clock generator 110 and a second control signal CNTL2 to the socket unit 120 so that the memory module is tested quickly and accurately. For instance, the first control signal CNTL1 may cause the clock generator 110 to generate the clock signal CLK, and the second control signal CNTL2 denote the start or the end of a test operation of a memory module placed in the socket unit 120. It is noted that the control signals CNTL1 and CNTL2 may be same signals.

The FPGA 140 transmits test data to and receives test data from the socket unit 120 using a predetermined test protocol, e.g., a Joint Test Action Group (JTAG) protocol. In particular, the FPGA 140 transmits test data to and from a buffer included in the memory module or modules placed in the socket unit 120. The test data transmitted by the FPGA 140 is a test program for testing memory modules placed the socket unit 120 using the JTAG protocol. The buffer of each memory module mounted in the socket unit 120 executes a test in accordance with the test program transmitted by the FPGA 140.

For example, the buffer may stored the received test program in a first register (e.g., a BIST engine register) and start execution of the test program in response to the control signal CNTL2 from the controller 130. Thereafter, after the memory module has been test, the buffer may store corresponding test results in a second register (e.g., an error log register). The FPGA 140 may then read the test results as test data from the second register and outputs the test results via the PC interface 150 to inform a user of the test results.

The PC interface 150 provides an operational interface between the memory module tester 100 and a PC. In addition to transmitting test results to a user, the PC interface 150 may also, for example, receive a memory test program (i.e., a BIST program) or test command from the user.

The power connector 160 applies externally supplied power to the memory module tester 100.

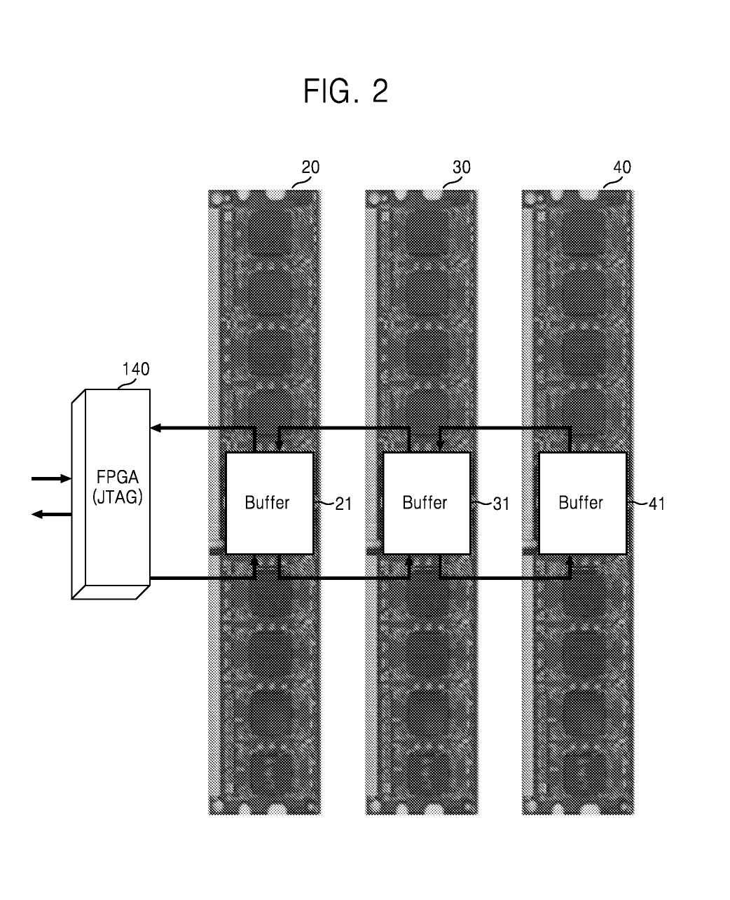

FIG. 2 is a diagram for use in further explaining an operation of memory module tester 100 illustrated in FIG. 1.

In particular, FIG. 2 schematically illustrates an example in which three memory modules, i.e., first, second, and third memory modules 20, 30, and 40, are placed in the memory module tester 100. As shown, the memory modules 20, 30, and 40 include respective first, second, and third buffers 21, 31, and 41, with each including an engine for testing the respective memory module. Further, in this example, the first through third buffers 21, 31, and 41 are connected in a daisy chain by the socket unit 120 of the memory module test 100.

Referring collectively to FIGS. 1 and 2, when a BIST program coded by a user is input to the FPGA 140, the FPGA 140 transmits the BIST program to the first buffer 21 using the JTAG protocol. The first buffer 21 stores the BIST program in an internal register, e.g., a BIST engine register, and then transmits the program to the second buffer 31. The second buffer 31 receiving the BIST program from the first buffer 21 also stores the program in an internal register, e.g., a BIST engine register, and then transmits the program to the third buffer 41.

The first through third buffers 21, 31, and 41 are controlled by the controller 130 to start the BIST program. When the memory module test executed by the BIST program is complete, each of the first through third buffers 21, 31, and 41 stores a test result in another internal register, e.g., an error log register. Thereafter, each of the first through third buffers 21, 31, and 41 is controlled by the controller 130 to transmit the test results to the FPGA 140. At this time, each of the first through third buffers 21, 31, and 41 transmits the test results back along the daisy chain path the BIST program was previously transmitted. For instance, the third buffer 41 transmits a test result for the third memory module 40 to the second buffer 31. The second buffer 31 transmits the test result for the third memory module 40 together with a test result for the second memory module 30 to the first buffer 21. The first buffer 21 transmits the test result for the second memory module 30 and the test result for the third memory module 40 together with a test result for the first memory module 20 to the FPGA 10.

In the example shown in FIG. 2, three memory modules are placed in the memory module tester 100. However, this is just an example, and the number of tested module is not limited. For instance, in the example of FIG. 1, up to 8 memory modules can be mounted in the memory module tester 100 and tested as described above.

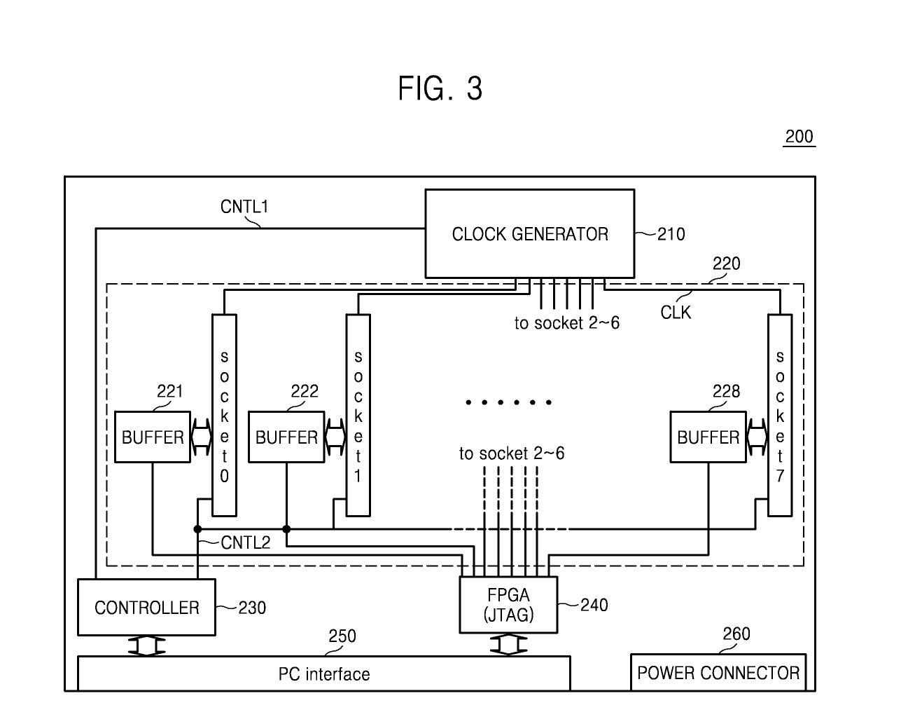

FIG. 3 is a schematic block diagram of a memory module tester 200 according to another embodiment of one or more inventive concepts described herein. In the embodiment illustrated in FIG. 3, a buffer with a BIST engine is configured separately from the memory module or modules being tested.

Referring to FIG. 3, the memory module tester 200 of this example includes a clock generator 210, a socket unit 220, a controller 230, a FPGA 240, a PC interface 250, and a power connector 260.

The clock generator 1210 generates a clock signal CLK in response on a first control signal CNTL1 from the controller 230, and outputs the clock signal CLK to each socket of the socket unit 220.

The socket unit 220 includes the one or more sockets 0 through 7, each of which is configured for mounting of a memory module (e.g., an unbuffered dual in-line memory module (UDIMM) or a registered dual in-line memory module (RDIMM)), and one or more buffers 221, 222, . . . , and 228 respectively corresponding to the one or more sockets 0 through 7. In other words, there is one-to-one correspondence between the buffers 221 through 228 and the sockets 0 through 7. In the example of this embodiment, each of the buffers 221 through 228 includes a self-testing engine for testing a memory module. In addition, the buffers 221 through 228 transmit test data to and receive test data from the FPGA 240. The sockets 0 through 7 are controlled by the controller 230.

The controller 230 controls the operation of the memory module tester 200 based on a predetermined control program or based on signal commands input through the PC interface 250. In particular, when a memory module to be tested is placed in the socket unit 220, the controller 230 initiates testing by outputting the control signal CNTL1 to the clock generator 210 and a control signal CNTL2 to the socket unit 220. For instance, the first control signal CNTL1 may cause the clock generator 210 to generate the clock signal CLK, and the second control signal CNTL2 denote the start or the end of a test operation of a memory module placed in the socket unit 220. It is noted that the control signals CNTL1 and CNTL2 may be same signals.

The FPGA 240 transmits test data to and receives test data from the buffers 221 through 228 included in the socket unit 220 using a predetermined test protocol, such as the JTAG protocol. In particular, the FPGA 240 transmits a test program for testing memory modules to the buffers 221 through 228 using the test protocol.

Each of the buffers 221 through 228 receiving the test program stores the test program in a first register (e.g., a BIST engine register) and starts the test program in response to the control signal CNTL2 from the controller 230. In other words, each of the buffers 221 through 228 tests a memory module corresponding thereto. Thereafter, each of the buffers 221 through 228 stores resultant test results in a second register (e.g., an error log register) and then the FPGA 240 reads the test results from the second register and outputs the same through the PC interface 250.

The PC interface 250 interfaces the memory module tester 200 and a PC. In particular, the PC interface 250 can receive a memory test program (i.e., a BIST program) desired by a user.

The power connector 260 applies external power to the memory module tester 200.

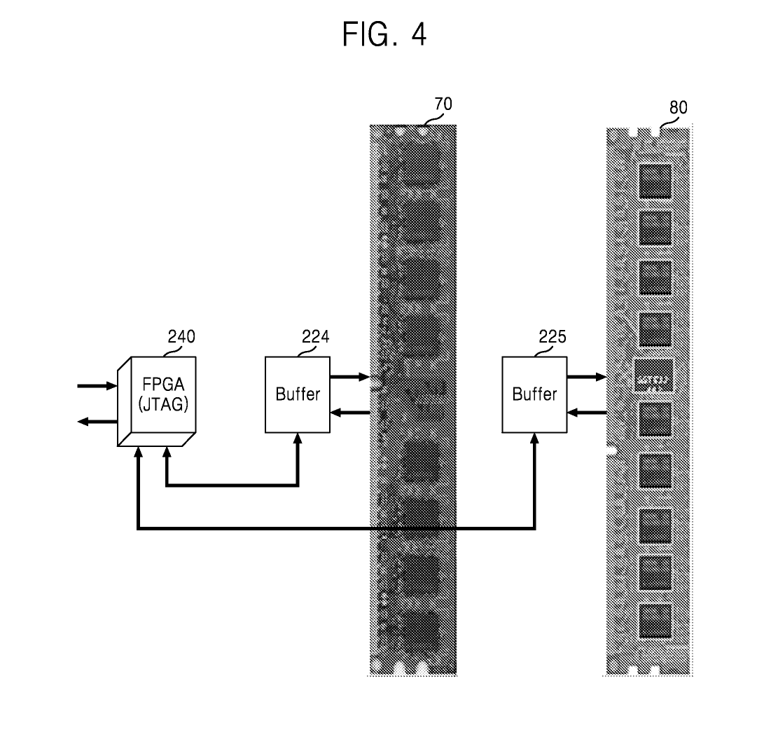

FIG. 4 is a diagram for explaining a test operation of the memory module tester 200 illustrated in FIG. 3.

In particular, FIG. 4 shows an example in which two memory modules, i.e., fourth and fifth memory modules 70 and 80, are placed in the memory module tester 200, and fourth and fifth buffers 224 and 225 of the memory module tester 200 are used and respectively correspond to the memory modules 70 and 80. As mentioned above, the buffers 224 and 225 include an engine for testing the corresponding memory modules 70 and 80, respectively. In other words, FIG. 4 illustrates a tester using buffer-on-board (BOB) technology.

Referring collectively to FIGS. 3 and 4, when a BIST program coded by a user is input to the FPGA 240, the FPGA 240 transmits the BIST program to the fourth and fifth buffers 224 and 225 using the JTAG protocol. Each of the fourth and fifth buffers 224 and 225 stores the BIST program in an internal register, e.g., a BIST engine register, and is controlled by the controller 230 to start the BIST program. When a memory module test by the BIST program ends, each of the fourth and fifth buffers 224 and 225 stores a test result in another internal register, e.g., an error log register. Thereafter, each of the fourth and fifth buffers 224 and 225 is controlled by the controller 230 to transmit the test results to the FPGA 240.

In the example shown in FIG. 4, two memory modules are placed in the memory module tester 200. However, this is just an example, and the number of tested module is not limited. For instance, in the example of FIG. 3, up to 8 memory modules can be mounted in the memory module tester 200 and tested as described above.

As described above, according to embodiments of the inventive concepts, a test program for testing a memory module and a test result are transmitted using a predetermined test protocol, such as the JTAG protocol, and therefore, a high-speed memory module can be tested using an “BIST” method for providing almost same environment as real environment.

While the present inventive concept has been particularly shown and described with reference to exemplary embodiments thereof, it will be understood by those of ordinary skill in the art that various changes in forms and details may be made therein without departing from the spirit and scope of the present inventive concept as defined by the following claims.

What is claimed is:

1. A memory module test system for testing a plurality of memory modules, comprising:
a plurality buffers in one-to-one correspondence the plurality of memory modules, each of the buffers including a self-test engine for testing a corresponding memory module;
an interface configured to receive a test program for testing the memory module; and
a gate array configured to transmit the test program to the buffers using a predetermined test protocol and to read test results of the test program from the buffers using the predetermined test protocol.

2. The memory module test system of claim 1, wherein the buffers are respectively included in the corresponding memory modules.

3. The memory module test system of claim 2, wherein the buffers are connected in a daisy chain.

4. The memory module test system of claim 1, wherein each buffer comprises a first register configured to store the test program, and a second register configured to store the test results.

5. The memory module test system of claim 1, wherein the gate array is a field programmable gate array (FPGA).

6. The memory module test system of claim 1, wherein the memory modules are selected from the group consisting of a fully buffered dual in-line memory module (FBDIMM), an unbuffered dual in-line memory module (UDIMM), and a registered dual in-line memory module (RDIMM).

7. The memory module test system of claim 1, wherein the predetermined test protocol is the Joint Test Action Group (JTAG) protocol.

8. A memory module tester comprising:
a socket for receiving a memory module to be tested;
a buffer operatively coupled to the socket;
an interface configured to receive a test program for testing the memory module; and
a gate array configured to transmit the test program to the buffer using a predetermined test protocol and test results of the test program from the buffers using the predetermined test protocol.

9. The memory module tester of claim 8, wherein the buffer comprises a first register configured to store the test program, and a second register configured to store the test result.

10. The memory module tester of claim 8, wherein the gate array is a field programmable gate array (FPGA).

11. The memory module tester of claim 8, further comprising a controller configured to control an operation of the memory module tester based on a predetermined control program or a signal input through the interface.

12. The memory module tester of claim 11, further comprising a clock generator configured to generate a clock signal based on a control signal from the controller and output the clock signal to the socket.

13. The memory module tester of claim 11, wherein the controller is further configured to generate a control signal for indicating the start or the end of a test of the memory module.

14. The memory module tester of claim 8, wherein the predetermined test protocol is the Joint Test Action Group (JTAG) protocol.
